(19) United States
(12) Patent Application Publication
(10) Pub. No.: US 2013/0105804 A1
(43) Pub. Date: May 2, 2013

(54) DISPLAY PANEL AND METHOD OF MANUFACTURING THE SAME

(71) Applicants: Sung Woo JUNG, Yongin-City (KR); Hee Yol LEE, Yongin-City (KR); Deok Hol KIM, Yongin-City (KR)

(72) Inventors: Sung Woo JUNG, Yongin-City (KR); Hee Yol LEE, Yongin-City (KR); Deok Hol KIM, Yongin-City (KR)

(21) Appl. No.: 13/661,182

(22) Filed: Oct. 26, 2012

(30) Foreign Application Priority Data
Oct. 26, 2011 (KR) 10-2011-0110134

(51) Int. Cl. H01L 33/52; H01L 33/08

(52) U.S. Cl. 257/59; 438/28; 257/E33.059; 257/E33.053

(57) ABSTRACT

A display panel having a non-display region and having a display region that includes a plurality of pixel regions, each of the pixel regions including a thin film transistor, the display panel including: an array substrate including the display region, the non-display region, a first base substrate including a gate line, a data line and a thin film transistor, an insulating layer covering the first base substrate, and a pixel electrode on the insulating layer; an opposite substrate over the array substrate; a light blocking pattern on the array substrate, the light blocking pattern surrounding the display region and intersecting the gate line and the data line; and an encapsulating element on the light blocking pattern, the encapsulating element bonding and sealing the array substrate and the opposite substrate, wherein: the thin film transistor is coupled to the gate line and the data line, the insulating layer has a contact hole exposing a drain electrode of the thin film transistor, and the pixel electrode contacts the thin film transistor through the contact hole.

### CROSS-REFERENCE TO RELATED APPLICATIONS

This U.S. non-provisional patent application claims priority under 35 U.S.C.§119 to Korean Patent Application No. 10-2011-0110134, filed on Oct. 26, 2011, in the Korean Intellectual Property Office, the entire contents of which are hereby incorporated by reference.

### BACKGROUND

1. Field

Embodiments of the inventive concepts relate to a display panel and a method of manufacturing the same.

2. Description of the Related Art

Conventionally, a display panel includes an array substrate and an opposite substrate, which are bonded with each other by an encapsulating element, and a liquid crystal layer interposed between the array and opposite substrates. The encapsulating element is disposed on a non-display region provided outside a display region. The encapsulating element may include a photo-curable material, and the formation of the encapsulating element may include disposing a light blocking layer between the encapsulating element and the opposite substrate and then irradiating the structure through the array substrate.

### SUMMARY

One or more embodiments may provide a display panel having a non-display region and having a display region that includes a plurality of pixel regions, each of the pixel regions including a thin film transistor, the display panel including: an array substrate including the display region, the non-display region, a first base substrate including a gate line, a data line and a thin film transistor, an insulating layer covering the first base substrate, and a pixel electrode on the insulating layer; an opposite substrate over the array substrate; a light blocking pattern on the array substrate, the light blocking pattern surrounding the display region and intersecting the gate line and the data line; and an encapsulating element on the light blocking pattern, the encapsulating element bonding and sealing the array substrate and the opposite substrate, wherein: the thin film transistor is coupled to the gate line and the data line, the insulating layer has a contact hole exposing a drain electrode of the thin film transistor, and the pixel electrode contacts the thin film transistor through the contact hole.

The light blocking pattern may be on the insulating layer. The light blocking pattern may include at least one of Mo, Cr, Al and Ti. The display panel may further include a dummy pattern between the light blocking pattern and the array substrate. The dummy pattern may be coplanar with the pixel electrode in the array substrate.

One or more embodiments may provide a method of manufacturing a display panel having a non-display region and having a display region that includes a plurality of pixel regions, each of the pixel regions including a thin film transistor, the method including: preparing an array substrate including the display region, the non-display region, a first base substrate including a gate line, a data line, and a thin film transistor, an insulating layer covering the first base substrate; forming a contact hole in the insulating layer, the contact hole exposing a drain electrode of the thin film transistor; forming a pixel electrode on the insulating layer, the pixel electrode contacting the thin film transistor through the contact hole; forming a light blocking pattern on the array substrate, the light blocking pattern surrounding the display region and intersecting the gate line and the data line; forming an encapsulating element on the light blocking pattern; bonding an opposite substrate to the array substrate using the encapsulating element; and illuminating a light incident through the opposite substrate onto the encapsulating element to cure the encapsulating element, wherein: the thin film transistor is coupled to the gate line and the data line. The light blocking pattern may include at least one of Mo, Cr, Al, and Ti.

One or more embodiments may provide a method of manufacturing a display panel having a non-display region and having a display region that includes a plurality of pixel regions, each of the pixel regions including a thin film transistor, the method including: preparing an array substrate including the display region, the non-display region, a first base substrate including a gate line, a data line, and a thin film transistor, an insulating layer covering the first substrate, forming a contact hole in the insulating layer, the contact hole exposing a drain electrode of the thin film transistor; forming a transparent conductive layer on the insulating layer, the transparent conductive layer contacting the thin film transistor through the contact hole; forming a light blocking layer on the transparent conductive layer; etching the transparent conductive layer and the light blocking layer using a half-tone mask to form a pixel electrode in each pixel region, a dummy pattern in the non-display region, and a light blocking pattern on the dummy pattern in the non-display region, the pixel electrode contacting the thin film transistor through the contact hole; forming an encapsulating element on the light blocking pattern; bonding an opposite substrate to the array substrate using the encapsulating element; and illuminating a light incident through the opposite substrate onto the encapsulating element to cure the encapsulating element. The light blocking pattern may include at least one of Mo, Cr, Al and Ti.

### BRIEF DESCRIPTION OF THE DRAWINGS

Example embodiments will be more clearly understood from the following brief description taken in conjunction with the accompanying drawings. FIGS. 1 through 12 represent non-limiting, example embodiments as described herein.

FIG. 1 illustrates an exploded perspective view of a display panel according to example embodiments;

FIG. 2 illustrates an enlarged plan view of a portion of an array substrate used for the display panel of FIG. 1;

FIG. 3 illustrates a sectional view of the display panel taken along a line I-I′ of FIG. 2;

FIGS. 4 through 6 illustrate sectional views of stages in a method of fabricating a display panel according to example embodiments;

FIG. 7 illustrates a sectional view of a display panel according to other example embodiments; and

FIGS. 8 through 12 illustrate sectional views of stages in a method of fabricating a display panel according to other example embodiments.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

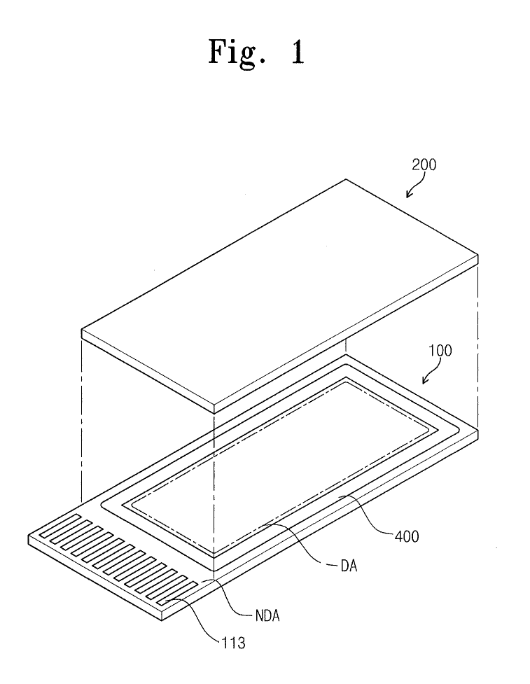

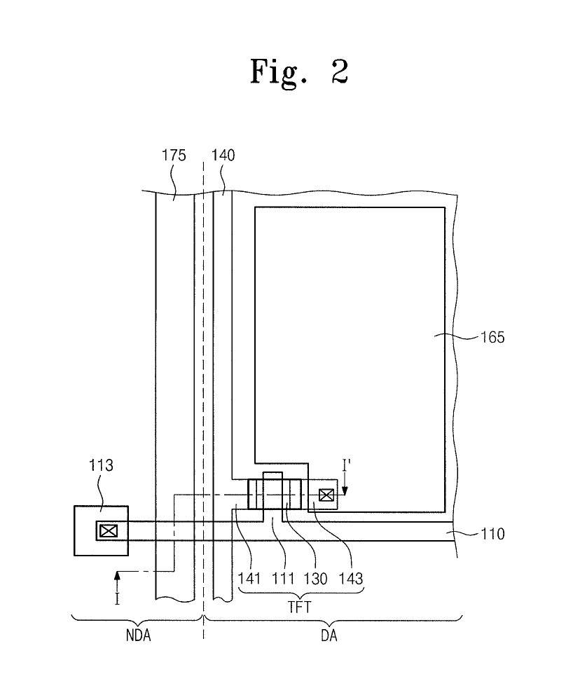

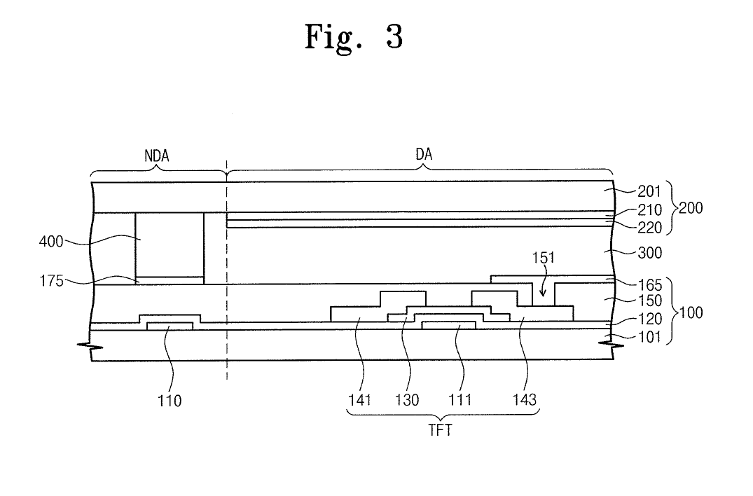

FIG. 1 illustrates an exploded perspective view of a display panel according to example embodiments. FIG. 2 illustrates an enlarged plan view of a portion of an array substrate used for the display panel of FIG. 1. FIG. 3 illustrates a sectional view of the display panel taken along a line I-I′ of FIG. 2.

Referring to FIGS. 1 through 3, a display panel according to example embodiments of the inventive concepts is configured to display an image. Example embodiments of the inventive concepts are not limited to a specific type of the display panel. For example, the display panel may be one of various display panels, such as an organic light emitting display (OLED) panel, a liquid crystal display (LCD) panel, an electrophoretic display (EPD) panel, an electrowetting display (EWD) panel, and so forth. In the case in which the display panel is a non-self-luminous display panel, such as LCD, EPD, and EWD panels, there may be additionally a backlight unit (not shown) for providing a light to the display panel. For the sake of simplicity, the description that follows will refer to an example of the present embodiment in which the display panel is the LCD panel.

The display panel may include an array substrate 100 with a display region DA and a non-display region NDA, an opposite substrate 200 facing the array substrate 100, and a liquid crystal layer 300 interposed between the array substrate 100 and the opposite substrate 200. The array substrate 100 and the opposite substrate 200 may be bonded using an encapsulating element 400, which may be provided in the non-display region NDA to surround the display region DA. In addition, a light blocking pattern 175 may be provided between the encapsulating element 400 and the array substrate 100.

The array substrate 100 may include a plurality of gate lines 110 extending along a first direction, and a plurality of data lines 140 extending along a second direction (e.g., across the first direction). The plurality of data lines 140 may be electrically isolated from the gate lines 110. A plurality of pixel regions may be arranged in a form of matrix, in the display region DA of the array substrate 100. In each pixel region, there may be a thin film transistor TFT, which is coupled with the gate and data lines 110 and 140, and a pixel electrode 165 coupled with the thin film transistor TFT.

In more detail, as shown in FIGS. 2 and 3, a gate electrode 111 of the thin film transistor TFT may be disposed in a portion of each pixel region of a first base substrate 101. The gate electrode 111 may extend from the gate line 110 into each pixel region.

A first insulating layer 120 may be provided on the gate line 110 and the gate electrode 111 to serve as a gate insulating layer, and a semiconductor pattern 130 may be provided on the first insulating layer 120 such that a portion thereof may overlap the gate electrode 111. The semiconductor pattern 130 may include a pair of doped regions disposed beside the gate electrode 111. The pair of doped regions may not overlap the gate electrode 111. One of the doped regions may be a source region and the other of the doped regions may be a drain region.

The source region may be coupled to a source electrode 141. The source electrode 141 may extend from the data line 140 to each pixel region. The drain region may be coupled to a drain electrode 143.

A second insulating layer 150 serving as a protection layer may be provided on the first base substrate 101 provided with the data line 140, the source electrode 141 and the drain electrode 143.

The second insulating layer 150 may include contact holes 151, which may be formed by a patterning process that exposes a portion of the drain electrode 143. The drain electrode 143 of the thin film transistor TFT may be coupled to the pixel electrode 165 on the second insulating layer 150 in the pixel region, through the contact hole 151.

In some embodiments, the gate line 110 and the data line 140 may extend to the non-display region NDA and connect to a pad portion 113 for connection with an external circuit (not shown). The pad portion 113 may be configured to deliver an external control signal to the thin film transistor TFT, and the thin film transistor TFT may be configured to switch the delivered control signal to the pixel electrode 165.

The opposite substrate 200 may include a color filter 210, which is disposed on a surface of a second base substrate 201 facing the array substrate 100, and a common electrode 220 disposed on the color filter 210. The color filter 210 may display a predetermined color using a light passing through the array substrate 100 and the liquid crystal layer 300. The common electrode 220 may face the pixel electrode 165. The common electrode 220 may generate an electric field, which may be used to determine a behavior of the liquid crystal layer 300, along with the pixel electrode 165, when a voltage is applied thereto. However, embodiments are not limited to the example described, in which the color filter 210 is provided on the opposite substrate 200. For example, the color filter 210 may be provided on the array substrate 110.

The liquid crystal layer 300 may be variably oriented along a specific direction, according to a voltage difference between the pixel electrode 165 and the common electrode 220. This change in orientation of the liquid crystal layer 300 may be used to control transmittance of a light provided from an external light source (e.g., a backlight unit), and thereby, enable the display panel to display an image. The liquid crystal layer 300 may be smectic liquid crystal molecules, nematic liquid crystal molecules, or cholesteric liquid crystal molecules. However, the liquid crystal layer 300 is not limited to a specific type of liquid crystal layer.

The encapsulating element 400 may be interposed between the array substrate 100 and the opposite substrate 200. For example, the encapsulating element 400 may be provided around the display region DA of the array substrate 100. The array substrate 100 and the opposite substrate 200 may be bonded by the encapsulating element 400. In addition, the encapsulating element 400 may include a photo-curable material that can be cured by, for example, an ultraviolet light.

The light blocking pattern 175 may be interposed between the encapsulating element 400 and the array substrate 100.

In more detail, the light blocking pattern 175 may be provided around the display region DA of the array substrate 100, and the encapsulating element 400 may be disposed on the light blocking pattern 175. In other words, the light blocking pattern 175 may be disposed on the second insulating layer 150 and overlap the gate line 110 or the data line 140 extending toward the non-display region NDA.

The light blocking pattern 175 may include at least one of Mo, Cr, Al and Ti. Alternatively, the light blocking pattern 175 may include an organic black matrix.

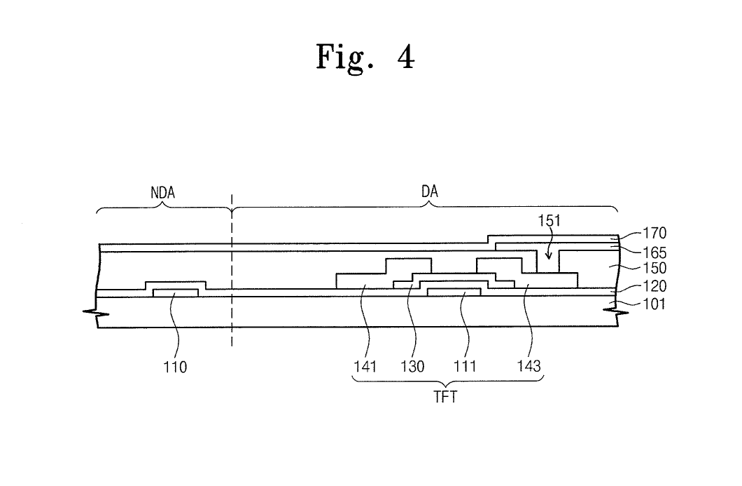

A method of fabricating a display panel according to example embodiments of the inventive concepts will be described with reference to FIGS. 4 through 6.

FIGS. 4 through 6 illustrate sectional views of stages in a method of fabricating a display panel according to example embodiments.

Referring to FIG. 4, a conductive material may be deposited on a first base substrate 101, and then, be patterned to form a plurality of gate lines 110 and a plurality of gate electrodes 111. Each of the gate electrodes 111 may extend from the gate line 110 into a corresponding one of the pixel regions. The gate line 110 may extend in a direction that is parallel to a first direction on the first base substrate 101. For example, the gate line 110 may be parallel to one surface of the first base substrate 101.

A first insulating layer 120 may be formed on the first base substrate 101. After the formation of the first insulating layer 120, a semiconductor pattern 130 may be formed in such a way that it may partially overlap the gate electrode 111. In some embodiments, the formation of the semiconductor pattern 130 may include depositing and patterning an amorphous silicon (a-Si) layer on the first insulating layer 120, and then doping the patterned amorphous silicon layer using the gate electrode 111 as an ion mask. As a result, doped regions may be formed in two portions of the patterned amorphous silicon layer located at both sides of the gate electrode 111.

A conductive material may be deposited on the first base substrate 101 provided with the semiconductor pattern 130, and be patterned to form data lines 140 (FIG. 2), source electrodes 141, and drain electrodes 143. Each of the source electrodes 141 may be connected to one of the doped regions of the semiconductor pattern 130, and each of the drain electrodes 143 may be connected to the other of the doped regions of the semiconductor pattern 130.

Thereafter, a second insulating layer 150 may be formed on the first base substrate 101 and be patterned to form contact holes 151. Each of the contact holes may expose a portion of a corresponding one of the drain electrodes 143. The second insulating layer 150 may be used as a protection layer and be formed by depositing at least one of an inorganic insulating layer and organic insulating layer. For example, the second insulating layer 150 may be a double layered structure including an inorganic insulating layer and an organic insulating layer, which are sequentially deposited.

A conductive material may be deposited on the second insulating layer 150 and then, be patterned to form pixel electrodes 165. The pixel electrodes 165 may be formed to include a transparent conductive material.

After the formation of the pixel electrodes 165, a light blocking layer 170 may be formed on the first base substrate 101. The light blocking layer 170 may be formed of at least one of Mo, Cr, Al or Ti. The light blocking layer 170 may also include an organic black matrix.

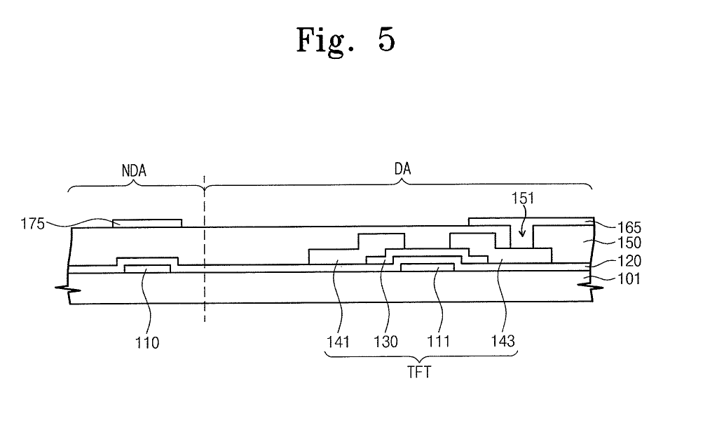

Referring to FIG. 5, the light blocking layer 170 may be patterned to form light blocking patterns 175, after which an array substrate 100 may be formed. The light blocking pattern 175 may be formed to surround the display region DA. In some embodiments, the light blocking pattern 175 may partially overlap the gate line 110 and/or the data line 140 (FIG. 2) extending toward the non-display region NDA.

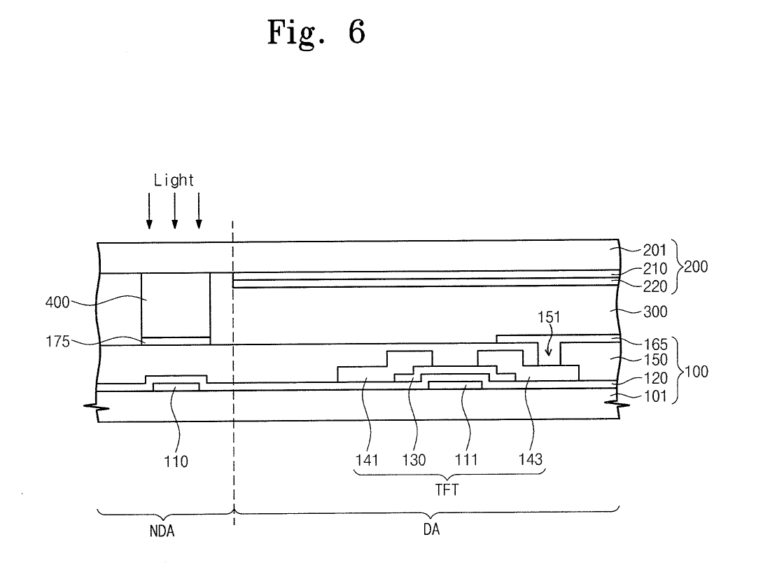

Referring to FIG. 6, an encapsulating element 400 may be formed on the light blocking pattern 175. The encapsulating element 400 may be formed to include a photo-curable material. In some embodiments, the encapsulating element 400 may be formed by a dispenser method or a screen printing method using a screen mask. When the encapsulating element 400 is formed using the screen printing method, it is possible to improve an alignment characteristic between the encapsulating element 400 and the light blocking pattern 175.

An opposite substrate 200 may be prepared, for example, after the formation of the encapsulating element 400. The preparation of the opposite substrate 200 may include forming a color filter 210 on a surface of a second base substrate 201 and forming a common electrode 220 on the color filter 210. In some embodiments, an insulating layer (not shown) may be formed between the color filter 210 and the common electrode 220.

Thereafter, the array substrate 100 and the opposite substrate 200 may be bonded in such a way that the common electrode 220 of the opposite substrate 200 faces the array substrate 100.

After the bonding of the array and opposite substrates 100 and 200, the encapsulating element 400 may be cured by a light incident through the opposite substrate 200 (i.e., a surface of the opposite substrate 200 opposite the array substrate 100). In some embodiments, optical properties of the incident light may vary according to the photo-curable material included in the encapsulating element 400. For example, if the photo-curable material is sensitive to a visible-light, the incident light may be selected to have a visible wavelength. Alternatively, if the photo-curable material is sensitive to an ultra-violet light, the incident light may be selected to have an ultra-violet wavelength.

Embodiments may not be limited to the afore-described example in which the encapsulating element 400 may be formed on the array substrate 100. For example, the encapsulating element 400 may be formed on a region of the opposite substrate 200 corresponding to the light blocking pattern 175.

Although not depicted, a liquid crystal layer 300 may be provided between the array substrate 100 and the opposite substrate 200. The formation of the liquid crystal layer 300 may include opening a portion of the encapsulating element 400 and injecting a liquid crystal material therethrough. Alternatively, the formation of the liquid crystal layer 300 may include attaching a sheet-like liquid crystal layer on the array substrate 100.

According to the afore-described display panel, the light blocking pattern 175 may be provided on the array substrate 100 and the encapsulating element 400 may be provided on the light blocking pattern 175. As a result, a curing light may be incident into the encapsulating element 400 through the opposite substrate 200. Accordingly, it may not be necessary to reduce an area to be occupied by the interconnection lines, such as the gate line 110 and the data line 140 (FIG. 2), which are disposed below the light blocking pattern 175 of the non-display region NDA of the array substrate 100. As such, a ratio of the area of the display region DA to the display panel may be increased.

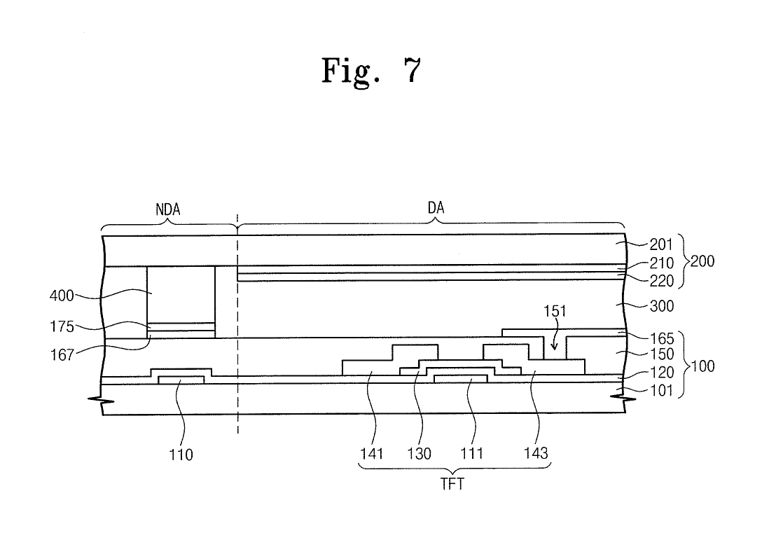

Hereinafter, other example embodiments of the inventive concepts will be described with reference to FIGS. 7 through 11. In the following description, for concise description, a previously described element may be identified by a similar or identical reference number without repeating the description thereof.

FIG. 7 illustrates a sectional view of a display panel according to other example embodiments.

Referring to FIG. 7, a display panel according to other example embodiments may include an array substrate 100 with a display region DA and a non-display region NDA, an opposite substrate 200 facing the array substrate 100, and a liquid crystal layer 300 interposed between the array substrate 100 and the opposite substrate 200. The array substrate 100 and the opposite substrate 200 may be bonded using an encapsulating element 400, which may be provided in the non-display region NDA, to surround the display region DA.

A light blocking pattern 175 may be provided between the encapsulating element 400 and the array substrate 100, and a dummy pattern 167 may be provided between the light blocking pattern 175 and the array substrate 100. In some embodiments, the dummy pattern 167 and the pixel electrode 165 may be provided on the same underlying layer. For example, the dummy pattern 167 may be provided on the second insulating layer 150 in the non-display region NDA to surround the display region DA.

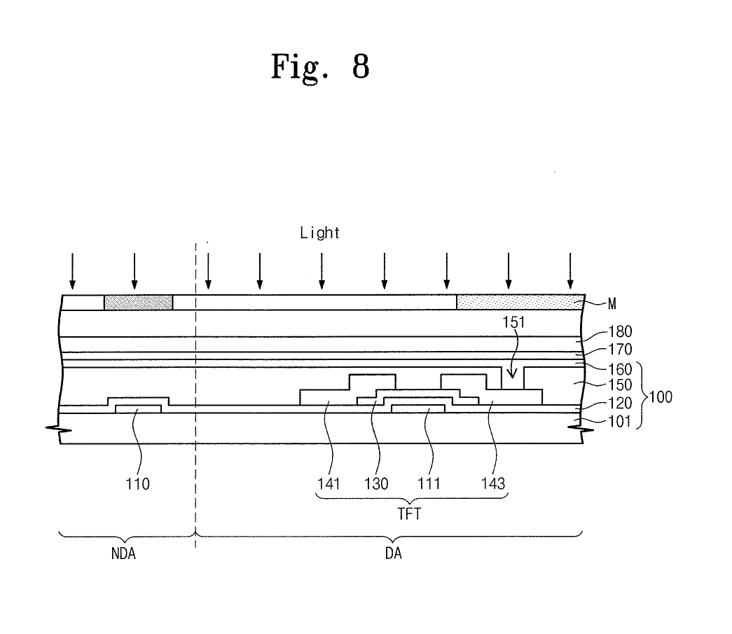

FIGS. 8 through 12 illustrate sectional views of stages in a method of fabricating a display panel according to other example embodiments.

Referring to FIG. 8, gate lines 110, data lines 140 (FIG. 2), and thin film transistors TFT may be formed on a first base substrate 101. Each of the thin film transistors TFT may be coupled to a corresponding one of the gate lines 110 and the corresponding one of the data lines 140.

Thereafter, a second insulating layer 150 may be formed on the first base substrate 101 provided with the gate lines 110, the data lines 140 (FIG. 2) and the thin film transistors TFT. The second insulating layer 150 may be patterned to form contact holes 151 partially exposing a drain electrode 143 of the thin film transistor TFT.

After the formation of the contact holes 151, a transparent conductive material may be deposited on the first base substrate 101 to form a transparent conductive layer 160, and a light blocking layer 170 may be formed on the transparent conductive layer 160.

A photo-sensitive layer 180 (e.g., photoresist) may be coated on the light blocking layer 170, and then, an exposure process using a half-tone mask M disposed on/over the light blocking layer 170 may be performed on the photo-sensitive layer 180.

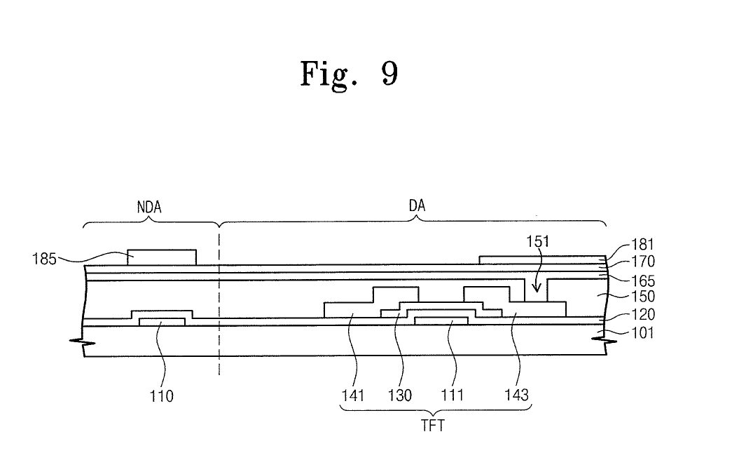

Referring to FIG. 9, mask patterns may be formed on the light blocking layer 170 by developing the photo-sensitive layer 180. The mask patterns may include a first mask pattern 181 disposed in the display region DA to partially cover each pixel region and a second mask pattern 185 disposed in the non-display region NDA to surround the display region DA.

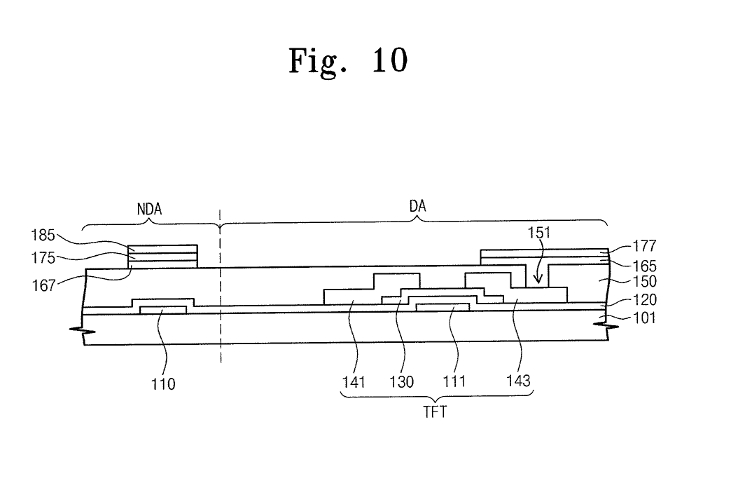

Referring to FIG. 10, a first etch process may be performed to etch the transparent conductive layer 160 and the light blocking layer 170 using the first and second mask patterns 181 and 185 as an etching mask. As the result of the first etch process, a pixel electrode 165, which is connected to the drain electrode 143 via the contact hole 151, may be formed in each pixel region of the display region DA, and a remaining light blocking pattern 177 may be formed on the pixel electrode 165. In addition, a dummy pattern 167 may be formed in the non-display region NDA that is coplanar with the pixel electrode 165 and surrounds the display region DA, and a light blocking pattern 175 may be formed on the dummy pattern 167.

In some embodiments, during the first etch process, the second mask pattern 185 may be thin, and/or the first mask pattern 181 may be removed.

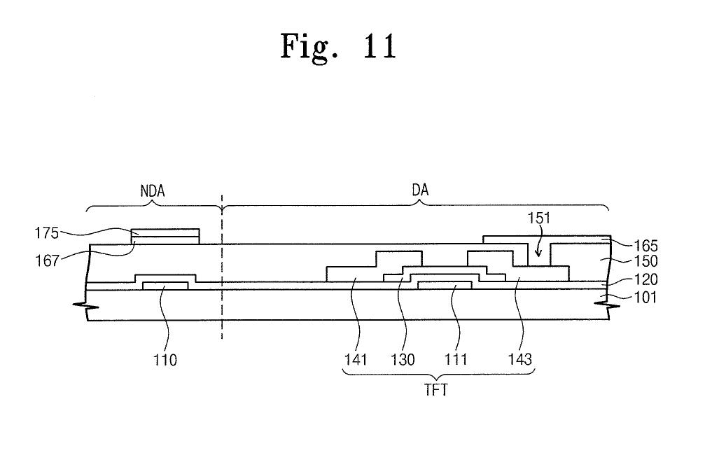

Referring to FIG. 11, a second etch process may be performed to remove the remaining light blocking pattern 177 on the pixel electrode 165 using the second mask pattern 185 as an etch mask, after the first etch process. As a result, the array substrate 100 may be prepared. In some embodiments, the second mask pattern 185 may be removed during the second etch process or by using an additional aching process.

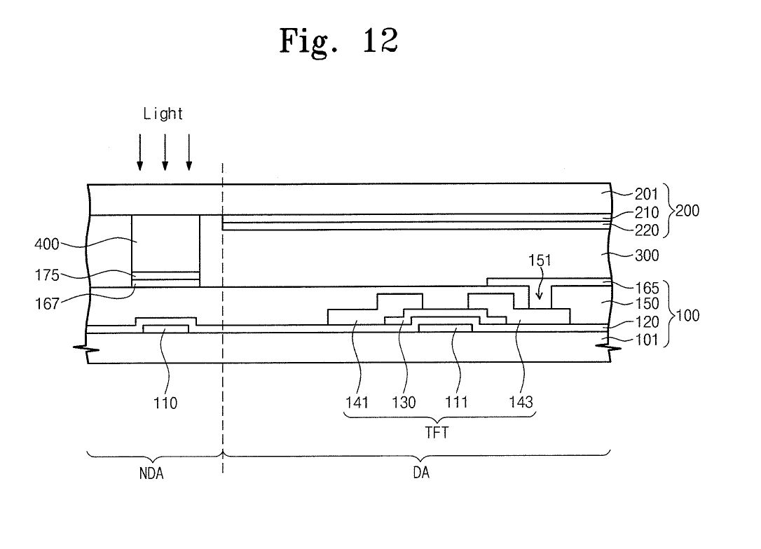

Referring to FIG. 12, an encapsulating element 400 may be formed on the light blocking pattern 175 and an opposite substrate 200 may be prepared.

Thereafter, the opposite substrate 200 may be disposed on the array substrate 100 in such a way that a color filter 210 and a common electrode 220 face the array substrate 100. The array substrate 100 and the opposite substrate 200 may then be bonded.

After the bonding of the array substrate 100 and the opposite substrate 200, the encapsulating element 400 may be cured by using a light incident through the opposite substrate 200 (i.e., a surface of the opposite substrate 200 opposite the array substrate 100).

By way of summation and review, during curing of an encapsulating element in a conventional display panel, light may be blocked by interconnection lines provided on the array substrate. This may prevent the encapsulating element from being sufficiently cured. In other words, failures related to the encapsulating element may occur. Furthermore, to sufficiently cure the encapsulating element in a conventional display panel, it is necessary to increase an aperture ratio, which is a ratio of an area occupied by the interconnection lines to a total area of the non-display region. Since the ratio of the area occupied by the interconnection lines to a total area of the non-display region increases, an area ratio of the non-display region to an area of display panel may be increased. Therefore, the area of the display region is reduced.

In contrast, according to one or more embodiments, a light blocking pattern may be provided between an encapsulating element and an array substrate. Thus, a curing light may be incident into the encapsulating element through the opposite substrate. As a result, it may be possible to reduce an area of a non-display region of the display panel and to increase an area of a display region of the display panel.

While example embodiments of the inventive concepts have been particularly shown and described, it will be understood by one of ordinary skill in the art that variations in form and detail may be made therein without departing from the spirit and scope of the attached claims.

What is claimed is:

1. A display panel having a non-display region and having a display region that includes a plurality of pixel regions, each of the pixel regions including a thin film transistor, the display panel comprising:
an array substrate including the display region, the non-display region, a first base substrate including a gate line, a data line and a thin film transistor, an insulating layer covering the first base substrate, and a pixel electrode on the insulating layer;
an opposite substrate over the array substrate;
a light blocking pattern on the array substrate, the light blocking pattern surrounding the display region and intersecting the gate line and the data line; and
an encapsulating element on the light blocking pattern, the encapsulating element bonding and sealing the array substrate and the opposite substrate, wherein:
the thin film transistor is coupled to the gate line and the data line,
the insulating layer has a contact hole exposing a drain electrode of the thin film transistor, and
the pixel electrode contacts the thin film transistor through the contact hole.

2. The display panel of claim 1, wherein the light blocking pattern is on the insulating layer.

3. The display panel of claim 1, wherein the light blocking pattern includes at least one of Mo, Cr, Al and Ti.

4. The display panel of claim 1, further comprising a dummy pattern between the light blocking pattern and the array substrate.

5. The display panel of claim 4, wherein the dummy pattern is coplanar with the pixel electrode in the array substrate.

6. A method of manufacturing a display panel having a non-display region and having a display region that includes a plurality of pixel regions, each of the pixel regions including a thin film transistor, the method comprising:
preparing an array substrate including the display region, the non-display region, a first base substrate including a gate line, a data line and a thin film transistor, and an insulating layer covering the first base substrate;
forming a contact hole in the insulating layer, the contact hole exposing a drain electrode of the thin film transistor;
forming a pixel electrode on the insulating layer, the pixel electrode contacting the thin film transistor through the contact hole;
forming a light blocking pattern on the array substrate, the light blocking pattern surrounding the display region and intersecting the gate line and the data line;
forming an encapsulating element on the light blocking pattern;
bonding an opposite substrate to the array substrate using the encapsulating element; and
illuminating a light incident through the opposite substrate onto the encapsulating element to cure the encapsulating element, wherein:
the thin film transistor is coupled to the gate line and the data line.

7. The method of claim 6, wherein the light blocking pattern includes at least one of Mo, Cr, Al, and Ti.

8. A method of manufacturing a display panel having a non-display region and having a display region that includes a plurality of pixel regions, each of the pixel regions including a thin film transistor, the method comprising:
preparing an array substrate including the display region, the non-display region, a first base substrate including a gate line, a data line and a thin film transistor, and an insulating layer covering the first substrate,
forming a contact hole in the insulating layer, the contact hole exposing a drain electrode of the thin film transistor;
forming a transparent conductive layer on the insulating layer, the transparent conductive layer contacting the thin film transistor through the contact hole;
forming a light blocking layer on the transparent conductive layer;
etching the transparent conductive layer and the light blocking layer using a half-tone mask to form a pixel electrode in each pixel region, a dummy pattern in the non-display region, and a light blocking pattern on the dummy pattern in the non-display region, the pixel electrode contacting the thin film transistor through the contact hole;
forming an encapsulating element on the light blocking pattern;
bonding an opposite substrate to the array substrate using the encapsulating element; and
illuminating a light incident through the opposite substrate onto the encapsulating element to cure the encapsulating element.

9. The method of claim 8, wherein the light blocking pattern includes at least one of Mo, Cr, Al and Ti.
